(19) United States
(12) Patent Application Publication
(10) Pub. No.: US 2026/0068411 A1
(43) Pub. Date: Mar. 5, 2026

(54) DISPLAY APPARATUS

(71) Applicant: AUO Corporation, Hsinchu City (TW)

(72) Inventors: Min-Ching Tsai, Hsinchu City (TW); Cheng-Chih Hsieh, Hsinchu City (TW)

(73) Assignee: AUO Corporation, Hsinchu City (TW)

(21) Appl. No.: 19/242,946

(22) Filed: Jun. 18, 2025

(30) Foreign Application Priority Data
Aug. 29, 2024 (TW) 113132464

(51) Int. Cl. H10H 29/80; H10H 29/855

(52) U.S. Cl. CPC H10H 29/882; H10H 29/855

(57) ABSTRACT

A display apparatus includes a driving circuit substrate, a first light-emitting element, a first scattering layer, and a second scattering layer. The first light-emitting element is disposed on the driving circuit substrate and is electrically connected to the driving circuit substrate. The first scattering layer is disposed on the first light-emitting element. The first scattering layer includes a first light-transmitting carrier and first scattering particles distributed in the first light-transmitting carrier. The second scattering layer is disposed on the first scattering layer. The first scattering layer is located between the second scattering layer and the first light-emitting element. The second scattering layer includes a second light-transmitting carrier and second scattering particles distributed in the second light-transmitting carrier. A diameter of a first scattering particle is greater than a diameter of a second scattering particle.

### CROSS-REFERENCE TO RELATED APPLICATION

This application claims the priority benefit of Taiwan application serial no. 113132464, filed on Aug. 29, 2024. The entirety of the above-mentioned patent application is hereby incorporated by reference herein and made a part of this specification.

### BACKGROUND

### Technical Field

The disclosure relates to an optoelectronic apparatus, and in particular to a display apparatus.

### Related Art

A light-emitting diode display panel includes a driving circuit substrate and multiple light-emitting diode elements transferred onto the driving circuit substrate. Inheriting the characteristics of light-emitting diodes, the light-emitting diode display panel has advantages such as power saving, high efficiency, high brightness, and fast response time. In addition, compared with an organic light-emitting diode display panel, the light-emitting diode display panel further has advantages such as easily adjustable colors, long emission lifetime, and no image burn-in. Therefore, the light-emitting diode display panel is considered as the next generation display technology. However, a beam emitted by the light-emitting diode element is prone to total internal reflection between the internal film layers of the light-emitting diode display panel, affecting the light extraction rate, so that the power consumption of the light-emitting diode display panel may not be further reduced.

### SUMMARY

The disclosure provides a display apparatus with good performance.

A display apparatus of the disclosure includes a driving circuit substrate, a first light-emitting element, a first scattering layer, and a second scattering layer. The first light-emitting element is disposed on the driving circuit substrate and electrically connected to the driving circuit substrate. The first scattering layer is disposed on the first light-emitting element. The first scattering layer includes a first light-transmitting carrier and multiple first scattering particles distributed in the first light-transmitting carrier. The second scattering layer is disposed on the first scattering layer. The first scattering layer is located between the second scattering layer and the first light-emitting element. The second scattering layer includes a second light-transmitting carrier and multiple second scattering particles distributed in the second light-transmitting carrier. A diameter of the first scattering particle is greater than a diameter of the second scattering particle.

### BRIEF DESCRIPTION OF THE DRAWINGS

FIG. 1 is a cross-sectional schematic view of a display apparatus according to an embodiment of the disclosure.

FIG. 2 is a cross-sectional schematic view of a splicing display according to an embodiment of the disclosure.

FIG. 3 is a cross-sectional schematic view of a display apparatus according to another embodiment of the disclosure.

### DESCRIPTION OF THE EMBODIMENTS

Reference is now made in detail to exemplary embodiments of the disclosure, examples

of which are illustrated in the accompanying drawings. Wherever possible, the same reference numerals are used in the drawings and descriptions to refer to the same or similar parts.

It should be understood that when an element such as a layer, a film, a region or a substrate is referred to as being “on” or “connected” to another element, it may be directly on or connected to another element, or intervening elements may also be present. In contrast, when an element is referred to as being “directly on” or “directly connected to” another element, there are no intervening elements present. As used herein, “connection” may refer to a physical and/or electrical connection. In addition, an “electrical connection” or “coupling” may be another element between two elements.

Considering the particular amount of measurement and measurement-related errors discussed (i.e., the limitations of the measurement system), the terminology “about,” “approximately,” “essentially,” or “substantially” used herein includes the average of the stated value and an acceptable range of deviations from the particular value as determined by those skilled in the art. For instance, the terminology “about” may refer to as being within one or more standard deviations of the stated value, or within ±30%, ±20%, ±10%, or ±5%. Furthermore, the terminology “about,” “approximately,” “essentially,” or “substantially” as used herein may be chosen from a range of acceptable deviations or standard deviations depending on the optical properties, etching properties, or other properties, rather than one standard deviation for all properties.

Unless otherwise defined, all terms (including technical and scientific terms) used herein have the same meaning as commonly understood by ordinary skilled persons in the field to which the disclosure belongs. It is further understood that terms, such as those defined in commonly used dictionaries, should be interpreted as having a meaning that is consistent with the meaning in the context of the relevant art and the disclosure, and is not be interpreted in an idealized or overly formal sense unless expressly so defined herein.

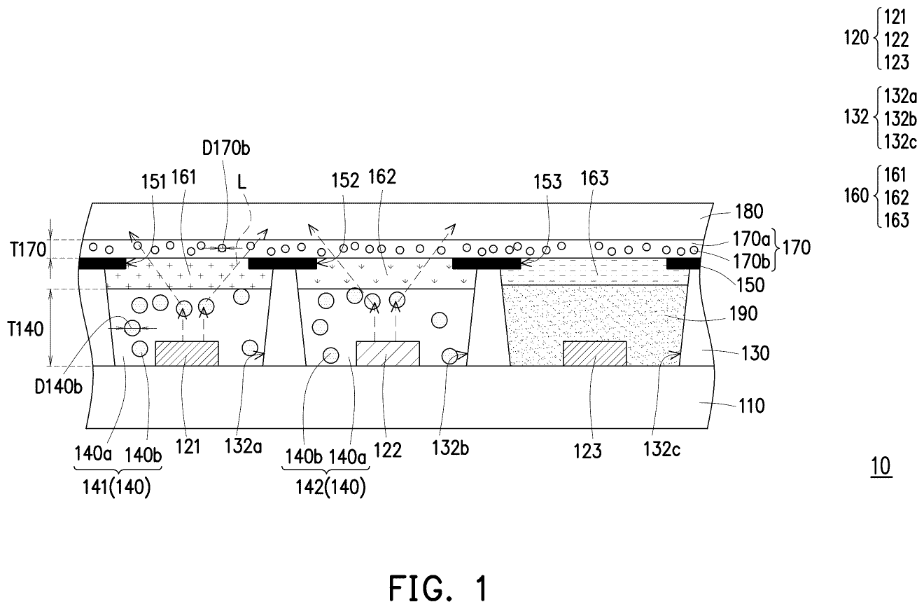

FIG. 1 is a cross-sectional schematic view of a display apparatus according to an embodiment of the disclosure. Referring to FIG. 1, a display apparatus 10 includes a driving circuit substrate 110. In some embodiments, the driving circuit substrate 110 has multiple sub-pixel driving circuits (not shown). For example, in some embodiments, each sub-pixel driving circuit may include a first transistor (not shown), a second transistor (not shown), and a capacitor (not shown). A first terminal of the first transistor is electrically connected to a corresponding data line (not shown). A control terminal of the first transistor is electrically connected to a corresponding scan line (not shown). A second terminal of the first transistor is electrically connected to a control terminal of the second transistor. A first terminal of the second transistor is electrically connected to a corresponding power line (not shown). The capacitor is electrically connected to the second terminal of the first transistor and the first terminal of the second transistor. However, the disclosure is not limited thereto. In other embodiments, the sub-pixel driving circuit may also be a circuit in other forms.

The display apparatus 10 further includes multiple light-emitting elements 120. The light-emitting elements 120 are disposed on the driving circuit substrate 110, and electrically connected to the driving circuit substrate 110. Specifically, the light-emitting elements 120 may be respectively electrically connected to the sub-pixel driving circuits of the driving circuit substrate 110. For example, in some embodiments, each light-emitting element 120 has a first electrode (not shown) and a second electrode (not shown), the first electrode is electrically connected to a second terminal of the second transistor of a corresponding sub-pixel driving circuit, and the second electrode is electrically connected to a common line (not shown) of the driving circuit substrate 110, but the disclosure is not limited thereto. In some embodiments, the light-emitting element 120 is, for example, a micro light-emitting diode (∥LED). However, the disclosure is not limited thereto. In other embodiments, the light-emitting element 120 may also be a mini light-emitting diode, an organic light-emitting element, or other types of elements.

In some embodiments, the light-emitting elements 120 may include a first light-emitting element 121, a second light-emitting element 122, and a third light-emitting element 123. For example, in some embodiments, the first light-emitting element 121 may be a light-emitting diode chip configured to emit blue light, the second light-emitting element 122 may be a light-emitting diode chip configured to emit green light, and the third light-emitting element 123 may be another light-emitting diode chip configured to emit blue light, but the disclosure is not limited thereto.

In some embodiments, the display apparatus 10 may optionally include a bank layer 130. The bank layer 130 is disposed on the driving circuit substrate 110 and has multiple openings 132.

The light-emitting elements 120 are respectively disposed in the openings 132 of the bank layer 130. In some embodiments, the openings 132 of the bank layer 130 may include a first opening 132a, a second opening 132b, and a third opening 132c, and the first light-emitting element 121, the second light-emitting element 122, and the third light-emitting element 123 are respectively located in the first opening 132a, the second opening 132b, and the third opening 132c of the bank layer 130. In some embodiments, the bank layer 130 may optionally have reflectivity to reflect a beam L emitted from the light-emitting element 120 to the outside of the display apparatus 10, but the disclosure is not limited thereto.

The display apparatus 10 further includes a first scattering layer 140. The first scattering layer 140 is disposed on the first light-emitting element 121. In some embodiments, the first scattering layer 140 is further disposed on the second light-emitting element 122. For example, in some embodiments, the first scattering layer 140 may include a first part 141 and a second part 142. The first part 141 is disposed in the first opening 132a of the bank layer 130 and covers the first light-emitting element 121. The second part 142 is disposed in the second opening 132b of the bank layer 130 and covers the second light-emitting element 122.

The first scattering layer 140 includes a first light-transmitting carrier 140a and multiple first scattering particles 140b distributed in the first light-transmitting carrier 140a. In some embodiments, an absolute value of a difference value between a refractive index of a first scattering particle 140b and a refractive index of the first light-transmitting carrier 140a is greater than 0.05. The refractive index of the first scattering particle 140b may be greater than or less than the refractive index of the first light-transmitting carrier 140a. For example, in some embodiments, the first light-transmitting carrier 140a may be a resin with a refractive index falling within a range of 1.495 to 1.52. The first scattering particle 140b may be an organic microsphere with a refractive index of about 1.66. In some embodiments, a material of the organic microsphere is, for example, melamine-formaldehyde copolymer, with a chemical structure as follows:

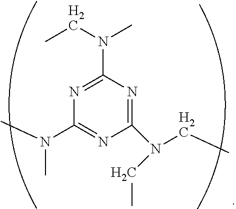

However, the disclosure is not limited thereto. In other embodiments, the material of the organic microsphere may also be other materials. Furthermore, the disclosure does not limit the first scattering particle 140b to be necessarily an organic microsphere. In other embodiments, the first scattering particle 140b may also be an inorganic microsphere, such as but not limited to a metal oxide microsphere.

In some embodiments, the display apparatus 10 further includes a color changing pattern 190 disposed in the third opening 132c of the bank layer 130 and covering the third light-emitting element 123. For example, in some embodiments, the color changing pattern 190 may convert the blue light emitted from the third light-emitting element 123 into red light.

In some embodiments, the display apparatus 10 further includes a light-shielding pattern layer 150 disposed on the bank layer 130. The light-shielding pattern layer 150 has a first opening 151, a second opening 152, and a third opening 153. In a top view of the display apparatus 10, the first light-emitting element 121, the second light-emitting element 122, and the third light-emitting element 123 are respectively located in the first opening 151, the second opening 152, and the third opening 153 of the light-shielding pattern layer 150.

In some embodiments, the display apparatus 10 may optionally include a color filter layer 160 located between the light-shielding pattern layer 150 and the first scattering layer 140. In some embodiments, the color filter layer 160 may include a first color filter pattern 161, a second color filter pattern 162, and a third color filter pattern 163. The first color filter pattern 161, the second color filter pattern 162, and the third color filter pattern 163 are respectively disposed in the first opening 151, the second opening 152, and the third opening 153 of the light-shielding pattern layer 150, and respectively overlap with the first light-emitting element 121, the second light-emitting element 122, and the third light-emitting element 123. In some embodiments, the first color filter pattern 161, the second color filter pattern 162, and the third color filter pattern 163 are, for example, a blue filter pattern, a green filter pattern, and a red filter pattern, respectively.

The display apparatus 10 further includes a second scattering layer 170 disposed on the first scattering layer 140. The first scattering layer 140 is located between the second scattering layer 170 and the first light-emitting element 121. The first scattering layer 140 is located between the second scattering layer 170 and the second light-emitting element 122. In some embodiments, the display apparatus 10 includes a color filter layer 160. The second scattering layer 170 and the first scattering layer 140 are respectively located on upper and lower sides of the color filter layer 160.

In some embodiments, the display apparatus 10 further includes a light-transmitting protection substrate 180 disposed opposite to the driving circuit substrate 110. The second scattering layer 170 is disposed between the light-transmitting protection substrate 180 and the color filter layer 160. The first scattering layer 140 is disposed between the color filter layer 160 and the light-emitting elements 120. In some embodiments, the second scattering layer 170 may be disposed on the entire surface of the light-transmitting protection substrate 180 and overlap with the first light-emitting element 121, the second light-emitting element 122, and the third light-emitting element 123, but the disclosure is not limited to thereto.

The second scattering layer 170 includes a second light-transmitting carrier 170a and multiple second scattering particles 170b distributed in the second light-transmitting carrier 170a. In some embodiments, an absolute value of a difference value between a refractive index of a second scattering particle 170b and a refractive index of the second light-transmitting carrier 170a is greater than 0.05. The refractive index of the second scattering particle 170b may be greater than or less than the refractive index of the second light-transmitting carrier 170a. For example, in some embodiments, the second light-transmitting carrier 170a may be a resin with a refractive index falling within a range of 1.495 to 1.52. The second scattering particle 170b may be an organic microsphere with a refractive index of about 1.66. In some embodiments, the material of the organic microsphere is, for example, melamine-formaldehyde copolymer, with a chemical structure formula as follows:

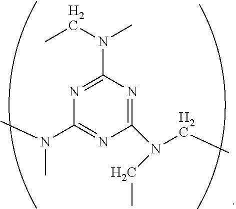

However, the disclosure is not limited thereto. In other embodiments, the material of the organic microsphere may also be other materials. Furthermore, the disclosure does not limit the second scattering particle 170b to necessarily be an organic microsphere. In other embodiments, the second scattering particle 170b may also be an inorganic microsphere, such as but not limited to the metal oxide microsphere.

It is worth noting that the diameter D140b of the first scattering particle 140b is greater than the diameter D170b of the second scattering particle 170b. For example, in some embodiments, the diameter D140b of the first scattering particle 140b may fall within a range of 1.1 μm to 1.3 μm, and the diameter D170b of the second scattering particle 170b may fall with a range of 0.3 μm to 0.5 μm.

A concentration of the second scattering particles 170b is greater than a concentration of the first scattering particles 140b, where the concentration of the second scattering particles 170b refers to a proportion of the second scattering particles 170b in the second scattering layer 170, and the concentration of the first scattering particles 140b refers to a proportion of the first scattering particles 140b in the first scattering layer 140. For example, in some embodiments, the concentration of the second scattering particles 170b may fall within a range of 26% to 40%, and the concentration of the first scattering particles 140b may fall within a range of 10% to 25%.

A thickness T140 of the first scattering layer 140 is greater than a thickness T170 of the second scattering layer 170. For example, in some embodiments, the thickness T140 of the first scattering layer 140 may fall within a range of 6 μm to 15 μm, and the thickness T170 of the second scattering layer 170 may fall within a range of 3 μm to 5 μm.

It is worth noting that through the refraction of the beam L between the first light-transmitting carrier 140a and the first scattering particle 140b of the first scattering layer 140, the beam L may be appropriately deflected to reduce the total internal reflection between the internal layers of the beam L, thereby improving a light extraction rate. Through the second scattering layer 170, the beam L may be scattered at a larger angle after leaving the first scattering layer 140, thereby mitigating a problem of large viewing angle color shift of the display apparatus 10. Through the mutual combination of the first scattering layer 140 and the second scattering layer 170, a display apparatus 10 with both low power consumption and low large viewing angle color shift may be realized.

It must be described here that the following embodiments continue to use the reference numerals and part of the content from the aforementioned embodiments, where the same reference numerals are used to represent the same or similar elements, and descriptions of identical technical content are omitted. Descriptions of the omitted parts should refer to the aforementioned embodiments, and are not repeated in the following embodiments.

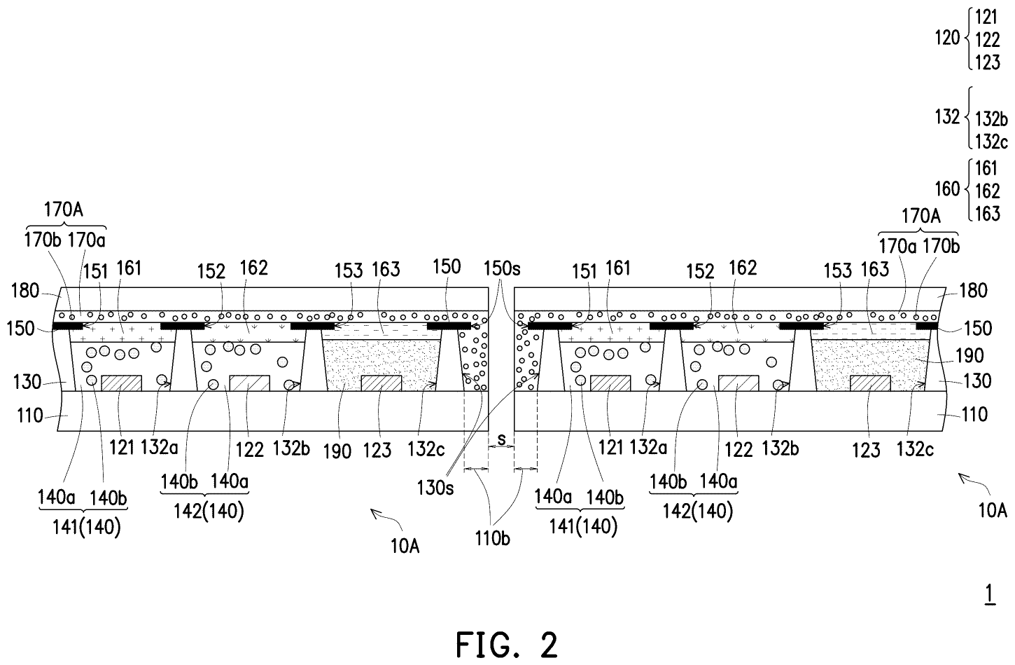

FIG. 2 is a cross-sectional schematic view of a splicing display according to an embodiment of the disclosure. The splicing display 1 in FIG. 2 may be formed by splicing multiple display apparatuses 10A. Each display apparatus 10A in FIG. 2 is similar to the display apparatus 10 in FIG. 1. The difference between the two lies in that the second scattering layer 170A of the display apparatus 10A in FIG. 2 is further disposed on an edge region 110b of the driving circuit substrate 110 and covers a side wall 150s of the light-shielding pattern layer 150 and a side wall 130s of the bank layer 130. A part of the second scattering layer 170A disposed on the edge region 110b of the driving circuit substrate 110 helps to fade a splicing seam s between the display apparatuses 10A, and also helps to improve the specular reflection problem of ambient light near the splicing seam s (that is, the edge regions 110b of adjacent driving circuit substrates 110).

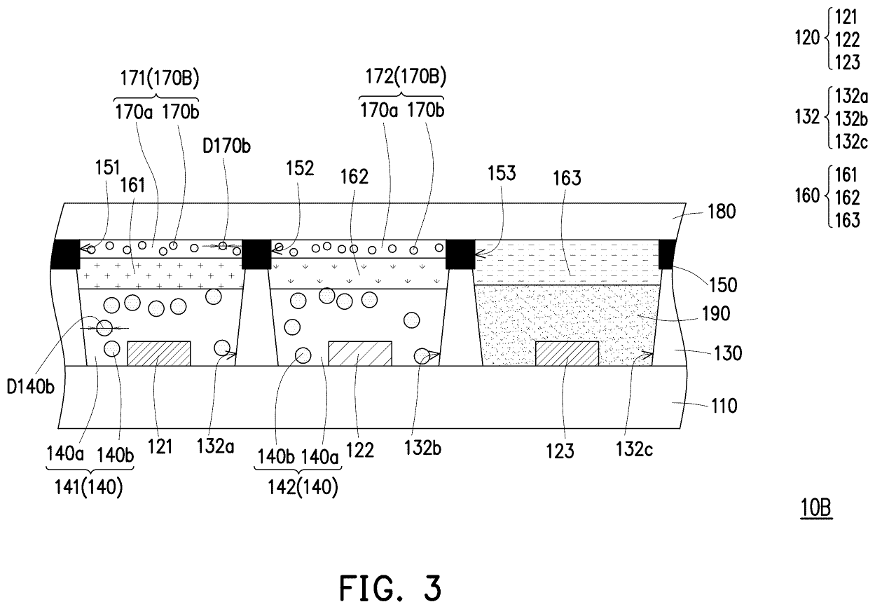

FIG. 3 is a cross-sectional schematic view of a display apparatus according to another embodiment of the disclosure. A display apparatus 10B in FIG. 3 is similar to the display apparatus 10 in FIG. 1. The difference between the two lies in that the second scattering layer 170B in FIG. 3 is a patterned scattering layer rather than a full-surface scattering layer.

In this embodiment, referring to FIG. 3, the light-shielding pattern layer 150 has a first opening 151 and a second opening 152 outside the first opening 151. In a top view of the display apparatus 10B, the first light-emitting element 121 and the second light-emitting element 122 are located in the first opening 151 and the second opening 152 respectively. Different from the embodiment in FIG. 1, in the embodiment of FIG. 3, the second scattering layer 170B includes a first part 171 and a second part 172 that are respectively disposed in the first opening 151 and the second opening 152 of the light-shielding pattern layer 150, with the first part 171 and the second part 172 being separated by the bank layer 130. In addition, in this embodiment, since the color changing pattern 190 has a sufficient scattering effect, the setting of the second scattering layer 170B may be omitted directly above the third light-emitting element 123.

The patterned second scattering layer 170B may avoid an optical crosstalk problem between different sub-pixels caused by the reduction in area of the light-shielding pattern layer 150 after the indirect increase in aperture ratio.

What is claimed is:

1. A display apparatus, comprising:
a driving circuit substrate;
a first light-emitting element, disposed on the driving circuit substrate, and electrically connected to the driving circuit substrate;
a first scattering layer, disposed on the first light-emitting element, and comprising:
a first light-transmitting carrier; and
a plurality of first scattering particles, distributed in the first light-transmitting carrier; and
a second scattering layer, disposed on the first scattering layer, wherein the first scattering layer is located between the second scattering layer and the first light-emitting element, and the second scattering layer comprises:
a second light-transmitting carrier; and
a plurality of second scattering particles, distributed in the second light-transmitting carrier, wherein a diameter of a first scattering particle is greater than a diameter of a second scattering particle.

2. The display apparatus according to claim 1, wherein the diameter of the first scattering particle falls within a range of 1.1 μm to 1.3 μm, and the diameter of the second scattering particle falls within a range of 0.3 μm to 0.5 μm.

3. The display apparatus according to claim 1, wherein a concentration of the plurality of second scattering particles is greater than a concentration of the plurality of first scattering particles.

4. The display apparatus according to claim 3, wherein the concentration of the plurality of second scattering particles falls within a range of 26% to 40%, and the concentration of the plurality of first scattering particles falls within a range of 10% to 25%.

5. The display apparatus according to claim 1, wherein a thickness of the first scattering layer is greater than a thickness of the second scattering layer.

6. The display apparatus according to claim 1, wherein a thickness of the first scattering layer falls within a range of 6 μm to 15 μm, and a thickness of the second scattering layer falls within a range of 3 μm to 5 μm.

7. The display apparatus according to claim 1, wherein an absolute value of a difference value between a refractive index of the first scattering particle and a refractive index of the first light-transmitting carrier is greater than 0.05.

8. The display apparatus according to claim 1, wherein an absolute value of a difference value between a refractive index of the second scattering particle and a refractive index of the second light-transmitting carrier is greater than 0.05.

9. The display apparatus according to claim 1, further comprising:
a second light-emitting element, disposed on the driving circuit substrate, and electrically connected to the driving circuit substrate, wherein the first scattering layer is further disposed on the second light-emitting element; and
a light-shielding pattern layer, having a first opening and a second opening, wherein in a top view of the display apparatus, the first light-emitting element and the second light-emitting element are respectively located in the first opening and the second opening;
wherein the second scattering layer comprises a first part and a second part respectively disposed in the first opening and the second opening of the light-shielding pattern layer.

10. The display apparatus according to claim 1, further comprising:
a light-shielding pattern layer, having a first opening, wherein in a top view of the display apparatus, the first light-emitting element is located in the first opening of the light-shielding pattern layer;
wherein the second scattering layer is further disposed on an edge region of the driving circuit substrate, and covers a side wall of the light-shielding pattern layer.

11. A display apparatus, comprising:
a driving circuit substrate;
a first light-emitting element, disposed on the driving circuit substrate, and electrically connected to the driving circuit substrate;
a first scattering layer, disposed on the first light-emitting element, and comprising:
a first light-transmitting carrier; and
a plurality of first scattering particles, distributed in the first light-transmitting carrier; and
a second scattering layer, disposed on the first scattering layer, wherein the first scattering layer is located between the second scattering layer and the first light-emitting element, and the second scattering layer comprises:
a second light-transmitting carrier; and
a plurality of second scattering particles, distributed in the second light-transmitting carrier; and
a color filter layer, wherein the first scattering layer and the second scattering layer are respectively disposed on opposite sides of the color filter layer, and the first scattering layer is located between the color filter layer and the driving circuit substrate.

12. The display apparatus according to claim 11, wherein a concentration of the plurality of second scattering particles is greater than a concentration of the plurality of first scattering particles.

13. The display apparatus according to claim 12, wherein the concentration of the plurality of second scattering particles falls within a range of 26% to 40%, and the concentration of the plurality of first scattering particles falls within a range of 10% to 25%.

14. The display apparatus according to claim 11, wherein a thickness of the first scattering layer is greater than a thickness of the second scattering layer.

15. The display apparatus according to claim 11, wherein an absolute value of a difference value between a refractive index of the first scattering particles and a refractive index of the first light-transmitting carrier is greater than 0.05.
